(19) United States
(12) Patent Application Publication
(10) Pub. No.: US 2016/0349338 A1
(43) Pub. Date: Dec. 1, 2016

(54) Quantitation of atoms by means of non-particulate radiation

(71) Applicants: James Bradley, WARMINSTER, PA (US); Robert A. E. Griebel, WARMINSTER, PA (US)

(72) Inventors: James Bradley, WARMINSTER, PA (US); Robert A. E. Griebel, WARMINSTER, PA (US)

(21) Appl. No.: 15/162,502

(22) Filed: May 23, 2016

Related U.S. Application Data
(60) Provisional application No. 62/166,084, filed on May 25, 2015.

(51) Int. Cl. G01R 33/36

(52) U.S. Cl. CPC G01R 33/36

(57) ABSTRACT

A driven signal is propagated to an independent resonator/sensor(s).

The independent resonator/sensor(s) functions as a frequency and/or amplitude moderator when the product introduced for measurement dampens the field.

The resonator/sensor(s) small design allows for improved sensitivity while utilizing less mass.

The measurement of product at a greater distance improves accuracy by reducing the variation factor of the container wall thickness.

The ability to position the resonator/sensor(s) in the orthogonal plane(s) allow for increased adaptability to new and existing production methods.

### BACKGROUND OF THE INVENTION

The present invention is in the technical field of verification. More notably, the present invention is in the technical field of Quantification of atoms in the pharmaceutical industries. Prior methods using microwave or magnetic resonance verification resulted in degradation of the contents, measurement that was below targeted standards and/or unadaptable to the production line.

### DESCRIPTION OF THE INVENTION

The primary advantages include non-degradation of the contents, improved measurement accuracy and increased distance of readability utilized for confined space(s) commonly found in the pharmaceutical packaging industries.

### SUMMARY OF THE INVENTION

The primary advantages include non-degradation of the contents, improved measurement accuracy and increased distance of readability utilized for confined space(s) commonly found in the pharmaceutical packaging industries.

### BRIEF DESCRIPTION OF THE DRAWING

FIG. 1 is a perspective view with a sample container of the present invention.

### DETAILED DESCRIPTION OF THE DRAWING

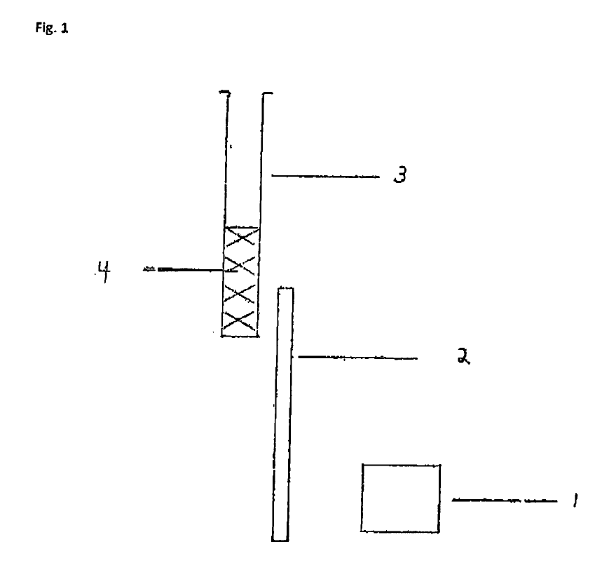

Referring now to the invention in more detail, in FIG. 1 there is a sample container 3 containing material 4 in relative proximity to the resonator/sensor 2 powered by the electric pulse generaₜor 1.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention.

### REFERENCES

### Citing Patents:

Publication number U.S. Pat. No. 3,418,428 A

Publication type Grant

Publication date Dec. 24, 1968

Filing date Oct. 18, 1965

Priority date Oct. 20, 1964

Also published as DEI 437593A1, DEI 43759382

Inventors Jean-Jacques Cuvelier

Original Assignee Acec

Export Citation BiBTeX, EndNote, RefMan

Patent Citations (1), Referenced by (1), Classifications (7)

External Links: USPTO, USPTO Assignment, Espacenet

Publication number U.S. Pat. No. 1,472,341 A

Publication type Grant

Publication date Oct. 30, 1923

Filing date Nov. 19, 1920

Priority date Nov. 19, 1920

Inventors Pickard Greenleaf Whittier

Original Assignee Wireless Specialty Apparatus

Export Citation BiBTeX, EndNote, RefMan

Classifications (5)

Publication number U.S. Pat. No. 7,002,346
U.S. Pat. No. 7,041,914
U.S. Pat. No. 7,061,239
U.S. Pat. No. 7,064,548

Filing date
Jun. 30, 2004
Jun. 30, 2004
Apr. 30, 2004
Apr. 30, 2004

Issue date
Feb. 21, 2006
May 9, 2006
Jun. 13, 2006
Jun. 20, 2006

Original Assignee
The BOC Group, Inc.
The BOC Group, Inc.
The BOC Group, Inc.
The BOC Group, Inc.

Title

Method for accurate determination of sample temperature in a NMR check weighing system Method for compensation of near-neighbor sample effects in a NMR check weighing system

Method for magnetic laid tracking in a NMR check weighing system

RF probe apparatus for NMR check weighing system

We claim:

1. Quantitation of atoms by means of non-particulate radiation utilizing the independent resonator/sensor(s).

2. The independent resonator/sensor(s) functions as a frequency and/or moderator when the product introduced for measurement dampens the field

3. The independent resonator/sensor(s) are of similar and/or dissimilar design.

4. The independent resonator/sensor(s) utilize discrete and/or shifting frequency(s) measurement.

5. The independent resonator/sensor(s) are configured dynamically to measure the container wall thickness and/or for additional measurement data.

6. The independent resonator/sensor(s) and/or container and/or associated equipment utilize active and/or passive shielding.
